(19) United States
(12) Patent Application Publication
(10) Pub. No.: US 2026/0371988 A1
(43) Pub. Date: Nov. 19, 2026

(54) SUBSTRATE PROCESSING APPARATUS

(71) Applicant: Samsung Electronics Co., Ltd., Suwon-si (KR)

(72) Inventors: Siyeong Yang, Suwon-si (KR); Seokhyun Kim, Suwon-si (KR); Yuyeon Kim, Suwon-si (KR); Jaemin Jung, Suwon-si (KR); Jaeho Jung, Suwon-si (KR)

(73) Assignee: Samsung Electronics Co., Ltd., Suwon-si (KR)

(21) Appl. No.: 19/455,673

(22) Filed: Jan. 21, 2026

(30) Foreign Application Priority Data
May 15, 2025 (KR) 10-2025-0063520
Jun. 4, 2025 (KR) 10-2025-0073130

(51) Int. Cl. H10P 72/00; B01J 20/02; B01J 20/28; C01B 33/037

(52) U.S. Cl. CPC H10P 72/0434; B01J 20/0225; B01J 20/0251; B01J 20/28007; C01B 33/037; H10P 72/0402

(57) ABSTRACT

Provided is a substrate processing apparatus including a boat configured to accommodate at least one substrate, a tube configured to define a reaction space of the at least one substrate, a vertical driving device configured to drive the boat in a vertical direction, a heating device surrounding the tube and configured to heat the reaction space, a gettering source gas supply device configured to supply a gettering source gas to the reaction space, a cleaning gas supply device configured to supply a cleaning gas to the reaction space, a first gettering layer on a surface of the boat, and a second gettering layer on a surface of the tube, wherein the first gettering layer and the second gettering layer include silicon (Si), and the first gettering layer and the second gettering layer further include at least one of phosphorus (P), oxygen (O), carbon (C), and nitrogen (N).

### CROSS-REFERENCE TO RELATED APPLICATIONS

This present application claims priority to and the benefit under 35 U.S.C. § 119(a)-(d) of Korean Patent Application No. 10-2025-0063520, filed on May 15, 2025, in the Korean Intellectual Property Office, and Korean Patent Application No. 10-2025-0073130, filed on Jun. 4, 2025, in the Korean Intellectual Property Office, the entire disclosures of which are incorporated herein by reference.

### FIELD

The disclosed concepts relate to a substrate processing apparatus and a substrate processing method, and more particularly, to a substrate processing apparatus and a substrate processing method for extracting impurities from a substrate.

### BACKGROUND

In manufacturing process of various types of semiconductor devices, a crystallization process may be performed to transform amorphous silicon (a-Si) into polycrystalline silicon (poly-Si). In general, the crystallization process may be performed based on metal induced crystallization (MIC) or metal induced lateral crystallization (MILC).

However, as a result of performing a crystallization process such as metal induced crystallization or metal induced lateral crystallization, a substrate may contain impurities (e.g., transition metals), and the impurities may deteriorate the performance of a semiconductor device. Therefore, a method capable of efficiently removing impurities contained in a substrate is demanded.

### SUMMARY

According to aspects of the disclosed concepts, there is provided a substrate processing apparatus including a boat configured to accommodate at least one substrate, a tube configured to define a reaction space of the at least one substrate, a vertical driving device configured to drive the boat in a vertical direction, a heating device surrounding the tube and configured to heat the reaction space, a gettering source gas supply device configured to supply a gettering source gas to the reaction space, a cleaning gas supply device configured to supply a cleaning gas to the reaction space, a first gettering layer on a surface of the boat, and a second gettering layer on a surface of the tube, wherein the first gettering layer and the second gettering layer include silicon (Si), and the first gettering layer and the second gettering layer further include at least one of phosphorus (P), oxygen (O), carbon (C), and nitrogen (N).

According to aspects of the disclosed concepts, there is provided a substrate processing apparatus including a boat configured to accommodate at least one substrate, a tube configured to define a reaction space of the at least one substrate, a heating device surrounding the boat and configured to heat the reaction space, a gettering source gas supply device configured to supply a gettering source gas to the reaction space, and a controller configured to control the heating device and the gettering source gas supply device, wherein the controller controls, in a gettering layer coating mode, the gettering source gas supply device to supply the gettering source gas into the reaction space when the boat is introduced into the reaction space, controls, in the annealing mode, the heating device to heat the reaction space when the boat loaded with the at least one substrate is introduced into the reaction space, the gettering layer coating mode is an operation mode for forming a first gettering layer covering the surface of the boat and a second gettering layer covering the surface of the tube, and the annealing mode is an operation mode for extracting a transition metal from at least one substrate to the first gettering layer and the second gettering layer.

According to aspects of the disclosed concepts, there is provided a substrate processing apparatus including a boat configured to accommodate at least one substrate, a tube configured to define a reaction space of the at least one substrate, a heating device surrounding the boat and configured to heat the reaction space, a gettering source gas supply device configured to supply a gettering source gas to the reaction space, a cleaning gas supply device configured to supply a cleaning gas to the reaction space, and a controller, wherein the controller controls, in a gettering layer coating mode, the gettering source gas supply device to supply the gettering source gas into the reaction space when the boat is introduced into the reaction space, controls, in the annealing mode, the heating device to heat the reaction space to a temperature of 500 °C or higher when the boat loaded with the at least one substrate is introduced into the reaction space, controls, in the cleaning mode, the cleaning gas supply device to supply the cleaning gas into the reaction space when the boat is introduced into the reaction space, the gettering layer coating mode is an operation mode for forming a first gettering layer covering the surface of the boat and a second gettering layer covering the surface of the tube, and the annealing mode is an operation mode for extracting a transition metal from at least one substrate to the first gettering layer and the second gettering layer, and the cleaning mode is an operation mode for etching the first gettering layer including the transition metal and the second gettering layer including the transition metal.

According to aspects of the disclosed concepts, there is provided a substrate processing method including, when a boat is introduced into a reaction space, forming a first gettering layer covering a surface of the boat and a second gettering layer covering a surface of a tube, loading at least one wafer to the boat, when the boat loaded with the at least one wafer is introduced into the reaction space, heating the reaction space, and unloading the at least one wafer from the boat, wherein the first gettering layer and the second gettering layer include silicon (Si), and the first gettering layer and the second gettering layer may further include at least one from among phosphorus (P), oxygen (O), carbon (C), and nitrogen (N).

According to some embodiments, the forming of the first gettering layer and the second gettering layer may include depositing the first gettering layer to a thickness of 10 nm or greater from a surface of the boat and depositing the second gettering layer to a thickness of 10 nm or greater from a surface of the tube.

According to some embodiments, the forming of the first gettering layer and the second gettering layer may include supplying a gettering source gas into the reaction space and heating the reaction space.

According to some embodiments, wherein the loading of the at least one wafer to the boat may include moving the boat out of the reaction space and disposing the at least one wafer on the first gettering layer, and a portion of a bottom surface of the at least one wafer may contact the first gettering layer.

According to some embodiments, the at least one wafer may include a substrate, a mold stack on the substrate, and a polycrystalline silicon layer surrounding the substrate and the mold stack, and the disposing of the at least one wafer may include disposing the at least one wafer such that the polycrystalline silicon layer contacts the first gettering layer.

According to some embodiments, the unloading of the at least one wafer from the boat may include moving the boat out of the reaction space and applying vibration to the boat to separate bond between the polycrystalline silicon layer and the first gettering layer.

According to some embodiments, the substrate processing method may include introducing the boat from which the at least one wafer is unloaded into the reaction space and removing the first gettering layer and the second gettering layer, wherein the first gettering layer and the second gettering layer may include nickel (Ni).

According to some embodiments, the removing of the first gettering layer and the second gettering layer may include supplying a cleaning gas into the reaction space, wherein the cleaning gas may include chlorine gas (Cl₂), hydrogen bromide gas (HBr), fluorine gas (F₂), and chlorine trifluoride gas (ClF₃).

According to some embodiments, the boat may include at least one of silicon oxide (SiO) and silicon nitride (SiN), and the tube may include at least one of silicon oxide (SiO) and silicon nitride (SiN).

According to some embodiments, the heating of the reaction space may include supplying an annealing gas from about 10 atm to about 100 atm into the reaction space and maintaining a temperature of the reaction space at 500 °C or higher from several hours to dozens of hours, wherein the annealing gas may include at least one of hydrogen gas (H₂), deuterium gas (D₂), and nitrogen gas (N₂).

### BRIEF DESCRIPTION OF THE DRAWINGS

Embodiments of the inventive concepts will be more clearly understood from the following detailed description taken in conjunction with the accompanying drawings in which:

FIG. 1 is a cross-sectional view of a substrate processing apparatus according to embodiments;

FIG. 2 is a flowchart for describing a substrate processing method of a substrate processing apparatus according to embodiments;

FIG. 3 is a cross-sectional view of a substrate processing apparatus according to embodiments;

FIG. 4 is a perspective view of a boat according to embodiments;
FIGS. 5A to 5E are cross-sectional views of a boat according to embodiments;

FIG. 6 is a cross-sectional view of a substrate processing apparatus according to embodiments;

FIG. 7 is an enlarged cross-sectional view of a substrate processing apparatus according to embodiments;

FIG. 8 is an enlarged cross-sectional view of a substrate processing apparatus according to embodiments; and

FIG. 9 is a cross-sectional view of a substrate processing apparatus according to embodiments.

### DETAILED DESCRIPTION

In this specification, a horizontal direction may include a first horizontal direction (X direction) and a second horizontal direction (Y direction) that intersect one another. A direction intersecting the first horizontal direction (X direction) and the second horizontal direction (Y direction) may be referred to as a vertical direction (Z direction). In this specification, a vertical level may be referred to as a height level of any component in the vertical direction (Z direction).

Hereinafter, embodiments will be described clearly and in detail to such an extent that one of ordinary skill in the art may easily practice the inventive concept.

The disclosed concepts provide a substrate processing apparatus capable of efficiently removing impurities contained in a substrate.

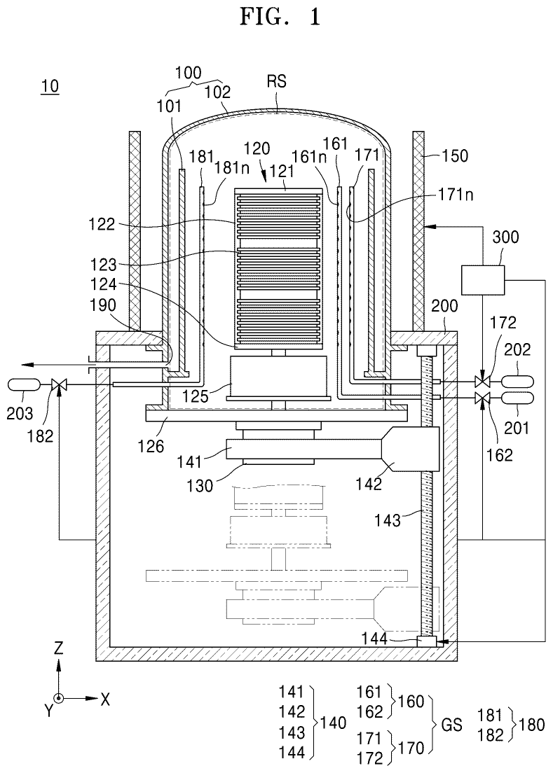

FIG. 1 is a cross-sectional view of a substrate processing apparatus 10 according to embodiments.

The substrate processing apparatus 10 may include a tube 100, a boat 120, a vibration device 130, a vertical driving device 140, a heating device 150, a gettering source gas supply device GS, a cleaning gas supply device 180, an exhaust port 190, a load lock chamber 200, and a controller 300.

The tube 100 may define a reaction space RS of substrates W. According to the inventive concept, the reaction space RS may mean a space where a substrate processing process is performed on substrates W. To perform the substrate processing process, the boat 120 loaded with the substrates W may be placed in the reaction space RS, and various types of gases may be supplied or heat may be applied thereto. Here, a substrate W is a target of a process performed by the substrate processing apparatus 10 and may include a wafer. The tube 100 may include a first tube 101 and a second tube 102.

For example, the first tube 101 may have a cylindrical shape that extends vertically and has open top and bottom, as shown in FIG. 1. According to some embodiments, the top of the first tube 101 may not be open, but may be closed. The second tube 102 may extend in a vertical direction, the upper portion of the second tube 102 may be implemented in a dome-like shape, and the lower portion of the second tube 102 may have an open shape. The second tube 102 may surround the first tube 101 in a lateral direction. The inner diameter of the second tube 102 may be greater than the outer diameter of the first tube 101.

The first tube 101 and the second tube 102 may include a heat-resistant material. Also, the first tube 101 and the second tube 102 may include a material resistant to a cleaning gas. Here, the cleaning gas may refer to a gas supplied to the reaction space RS in a cleaning mode of the substrate processing apparatus 10 described later. For example, the first tube 101 and the second tube 102 may include silicon oxide (SiO) or silicon nitride (SiN).

The boat 120 may accommodate at least one substrate W. The boat 120 may be introduced into the reaction space RS with at least one substrate W loaded thereon, or may be introduced into the reaction space RS without the substrate W loaded thereon. The boat 120 may include a top plate 121, a rod 122, a support structure 123, a bottom plate 124, a support 125, and a lid member 126. The boat 120 may also include a heat-resistant material or a material resistant to cleaning gas. For example, the boat 120 may include silicon oxide (SiO) or silicon nitride (SiN).

The rod 122 may be a pillar extending in the vertical direction and interconnecting the top plate 121 and the bottom plate 124. The boat 120 may include at least one rod 122. At least one rod 122 may be disposed near edges of the top plate 121 and the bottom plate 124. For example, the boat 120 may include four rods 122. At this time, the four rods 122 may be arranged at equal intervals along the circumference of the top plate 121 and the bottom plate 124. Also, the four rods 122 may be arranged at different intervals along the circumference of the top plate 121 and the bottom plate 124. The number of rods 122 included in the boat 120 may vary, e.g., 1, 2, or 3.

The support structure 123 is a component for supporting the substrate W and may be positioned to protrude horizontally from the rod 122. The support structure 123 may protrude horizontally from the rod 122 toward the central axis of the boat 120. A plurality of support structures 123 may be arranged at regular intervals in the vertical direction or at different intervals within one rod 122. The number of substrates W that the boat 120 may accommodate may be determined based on the number of support structures 123 included in the boat 120. For example, the boat 120 may accommodate from 25 substrates W to 200 substrates W. However, the number of the substrates W that the boat 120 may accommodate is not limited to the examples described above.

The support 125 has a cylindrical body and may include a pillar that is in direct contact with the bottom plate 124 in a vertical direction. The support 125 may support the bottom plate 124 such that the boat 120 may be stably fixed while the process is being performed. The lid member 126 may be connected to the lower end of the tube 100, and the lower opening of the tube 100 may be closed by the lid member 126. Here, for connection between the lid member 126 and the second tube 102, sealing members may be placed between a upper surface of the lid member 126 and a bottom surface of the second tube 102.

The vibration device 130 may be disposed below the boat 120 and apply vibration to the boat 120. In the process of unloading the substrate W described later, the vibration device 130 may vibrate the boat 120 such that the substrate W may be stably unloaded from the support structure 123. The vibration applied by the vibration device 130 to the boat 120 may include horizontal vibration and/or vertical vibration. The vibration device 130 may include, for example, an electric motor, a piezo actuator, etc.

The vertical driving device 140 may drive the boat 120 in a vertical direction. To this end, the vertical driving device 140 may include a horizontal arm 141, a connecting block 142, a drive shaft 143, and a motor 144.

The drive shaft 143 may be fixed to the load lock chamber 200. Here, the load lock chamber 200 may be placed at the bottom of the tube 100, and the space defined by the load lock chamber 200 may serve as an intermediate space between the reaction space RS defined by the tube 100 and the external space. The load lock chamber 200 may include an introduction port for introducing the substrate W. The drive shaft 143 may be coupled to the motor 144 and rotate by rotational force provided from the motor 144. For example, the drive shaft 143 may be implemented as a lead screw configured to rotate by rotational force. The horizontal arm 141 may be connected to the drive shaft 143 by a connecting block 142, and the horizontal arm 141 may move in the vertical direction based on the rotational drive of the drive shaft 143. As the horizontal arm 141 moves in the vertical direction, the boat 120 connected to the horizontal arm 141 may also be driven in the vertical direction.

In the above descriptions, it has been described that the vertical driving device 140 may include the horizontal arm 141, the connecting block 142, the drive shaft 143, and the motor 144. However, this is merely an example, and it is obvious that the vertical driving device 140 may include various types of components that may drive the boat 120 in the vertical direction.

The heating device 150 may be a component for heating the reaction space RS and placed apart from the tube 100. According to some embodiments, as shown in FIG. 1, the heating device 150 may be positioned laterally spaced from the tube 100. However, the heating device 150 may be placed in various locations, such as inside the tube 100 or inside the reaction space RS. The heating device 150 may include a plurality of heating coils. However, the heating device 150 may be implemented as various types of devices capable of heating the reaction space RS based on radiant heat (e.g., light heating method), indirect heating method using a refrigerant, etc.

The gettering source gas supply device GS may supply a gettering source gas to the reaction space RS. According to the inventive concept, the gettering source gas may refer to various types of gases supplied to the reaction space RS to form a gettering layer. For example, the gettering source gas may include various types of gases such as SiH₄, PH₃, CH₄, NH₃, N₂, tetraethoxysilane (TEOS), and methylsilane (CH₃SiH₃).

According to some embodiments, the gettering source gas supply device GS may include a first gas supply device 160 and a second gas supply device 170. According to some embodiments, the first gas supply device 160 may include a first gas supply pipe 161 and a first gas valve 162, and the second gas supply device 170 may include a second gas supply pipe 171 and a second gas valve 172. The first gas supply pipe 161 may include a plurality of first gas nozzles 161n, and the second gas supply pipe 171 may include a plurality of second gas nozzles 171n. The plurality of first gas nozzles 161n and the plurality of second gas nozzles 171n may each inject various types of gettering source gases toward the reaction space RS.

A first gas supply source 201 may be connected to the first gas supply device 160, and a second gas supply source 202 may be connected to the second gas supply device 170. The first gas supply source 201 and the second gas supply source 202 may supply a gettering source gas to the first gas supply device 160 and the second gas supply device 170, respectively. The first gas supply source 201 and the second gas supply source 202 may each be implemented as a gas storage tank that stores a gettering source gas. Although FIG. 1 shows that the gettering source gas supply device GS includes only the first gas supply device 160 and the second gas supply device 170, this is merely an example. The gettering source gas supply device GS may include various numbers of gas supply devices, e.g., three or more gas supply devices, or only one gas supply device.

The cleaning gas supply device 180 may supply a cleaning gas to the reaction space RS. The cleaning gas supply device 180 may include a cleaning gas supply pipe 181 and a cleaning gas valve 182. According to the inventive concept, the cleaning gas may mean a gas that is injected to etch gettering layers formed on surfaces of the tube 100 and the boat 120. For example, the cleaning gas may include at least one of Cl₂, HBr, F₂, and ClF₃. A third gas supply source 203 may supply a cleaning gas to the cleaning gas supply device 180. The third gas supply source 203 may be implemented as a gas storage tank that stores a cleaning gas.

The exhaust port 190 may be configured to discharge particles inside the reaction space RS toward the outside of the tube 100. The exhaust port 190 may be disposed to penetrate through at least a portion of the second tube 102 in a horizontal direction and may be connected to an external exhaust pump (not shown). A gettering source gas or a cleaning gas introduced into the reaction space RS may also be discharged to the outside through the exhaust port 190, and reaction byproducts generated during a substrate processing process may also be discharged to the outside through the exhaust port 190.

The controller 300 may be operatively connected to the vertical driving device 140, the heating device 150, the gettering source gas supply device GS, and the cleaning gas supply device 180, and may control the overall operations of the substrate processing apparatus 10. The controller 300 may be implemented in hardware, firmware, software, or any combination thereof. For example, the controller 300 may include a computing device like a workstation computer, a desktop computer, a laptop computer, and a tablet computer. The controller 300 may include a complex processor such as a microprocessor, a central processing unit (CPU), and a graphics processing unit (GPU), a processor configured by software, dedicated hardware, or firmware. The controller 300 may be implemented by, for example, a general-purpose computer or application-specific hardware such as a digital signal processor (DSP), a field programmable gate array (FPGA), and an application specific integrated circuit (ASIC).

The controller 300 may transmit a control signal corresponding to each operation mode of the substrate processing apparatus 10 to at least one of the vertical driving device 140, the heating device 150, the gettering source gas supply device GS, and the cleaning gas supply device 180. According to the inventive concept, operation modes of the substrate processing apparatus 10 may include a gettering layer coating mode, an annealing mode, and a cleaning mode. For example, the controller 300 may control the first gas valve 162 and the second gas valve 172 of the gettering source gas supply device GS to supply a gettering source gas to the reaction space RS in the gettering layer coating mode. In another example, the controller 300 may control the heating device 150 to heat the reaction space RS in the annealing mode. Also, the controller 300 may control the cleaning gas valve 182 to supply a cleaning gas to the reaction space RS in the cleaning mode.

According to the inventive concept, the gettering layer coating mode may mean an operation mode for forming a first gettering layer covering a surface of the tube 100 and a second gettering layer covering a surface of the boat 120. The annealing mode may mean an operation mode in which an impurity (e.g., a transition metal) is extracted from at least one substrate W into a first gettering layer and a second gettering layer. Also, the cleaning mode may mean an operation mode for etching the first gettering layer containing the impurity and the second gettering layer containing the impurity. The substrate processing apparatus 10 according to embodiments may operate in the order of the gettering layer coating mode, the annealing mode, and the cleaning mode, and thus may efficiently remove impurities present in the substrate W with only one insertion and one removal of the substrate W into and from the reaction space RS. In simple terms, the substrate processing apparatus 10 may remove impurities present in the substrate W through only a single process treatment of the substrate W, thereby simplifying the overall flow of a semiconductor manufacturing process. In the descriptions of the drawings below, methods of operating the substrate processing apparatus 10 in each of the operation modes including the gettering layer coating mode, the annealing mode, and the cleaning mode will be described in detail.

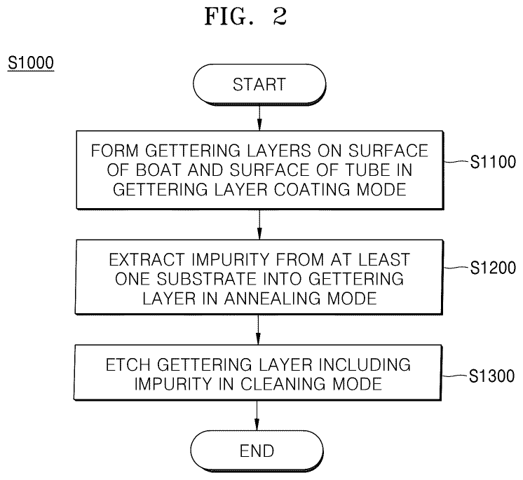

FIG. 2 is a flowchart for describing a substrate processing method S1000 of the substrate processing apparatus 10 according to embodiments. FIG. 2 will be described with reference to FIG. 1.

Referring to FIG. 2, in operation S1100, the substrate processing apparatus 10 may operate in the gettering layer coating mode. In detail, the substrate processing apparatus 10 may form a gettering layer on the surface of the boat 120 and the surface of the tube 100 in the gettering layer coating mode. Here, for convenience of explanation, a gettering layer formed on the surface of the boat 120 is referred to as a “first gettering layer”, and a gettering layer formed on the surface of the tube 100 is referred to as a “second gettering layer”.

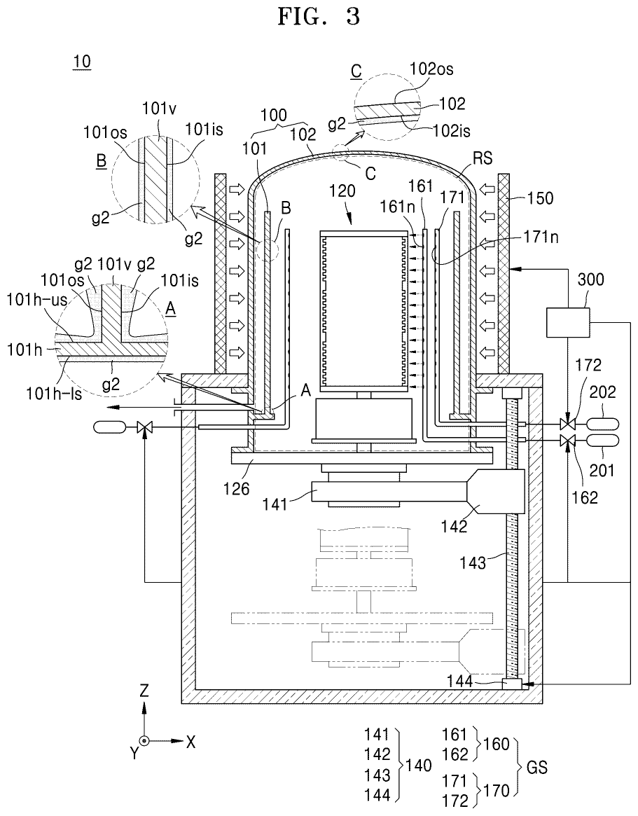

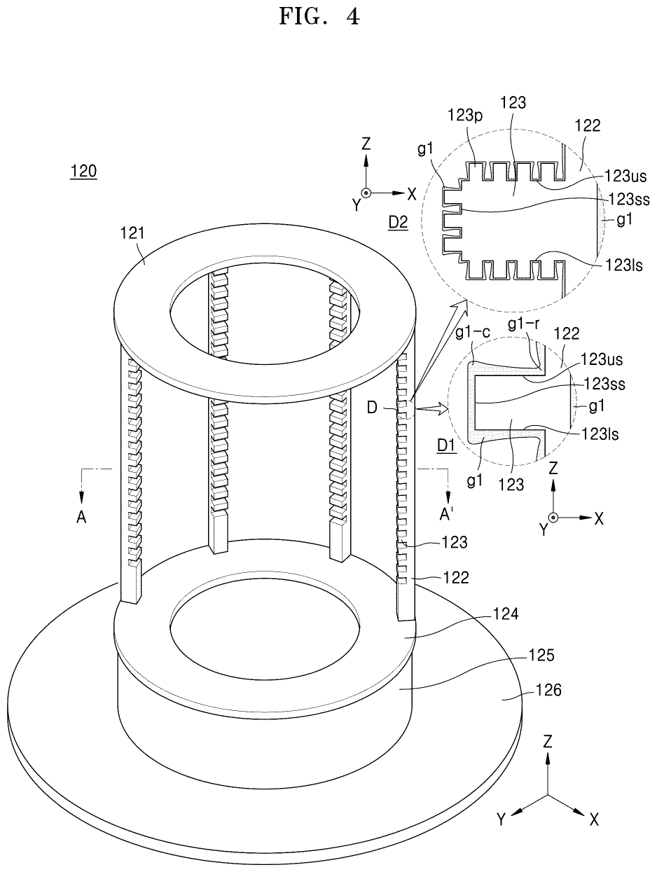

In the gettering layer coating mode, the controller 300 may control the vertical driving device 140 such that the boat 120 without the substrate W loaded thereon is introduced into the reaction space RS. When the boat 120 is introduced into the reaction space RS, the controller 300 may control the gettering source gas supply device GS such that the gettering source gas is supplied to the reaction space RS. As the gettering source gas is supplied, the first gettering layer and the second gettering layer may be formed. The operation of the substrate processing apparatus 10 in the gettering layer coating mode will be described in detail in the description of FIG. 3 below.

Next, in operation S1200, the substrate processing apparatus 10 may operate in the annealing mode. In detail, the substrate processing apparatus 10 may extract impurities from the substrate W to the gettering layer in the annealing mode.

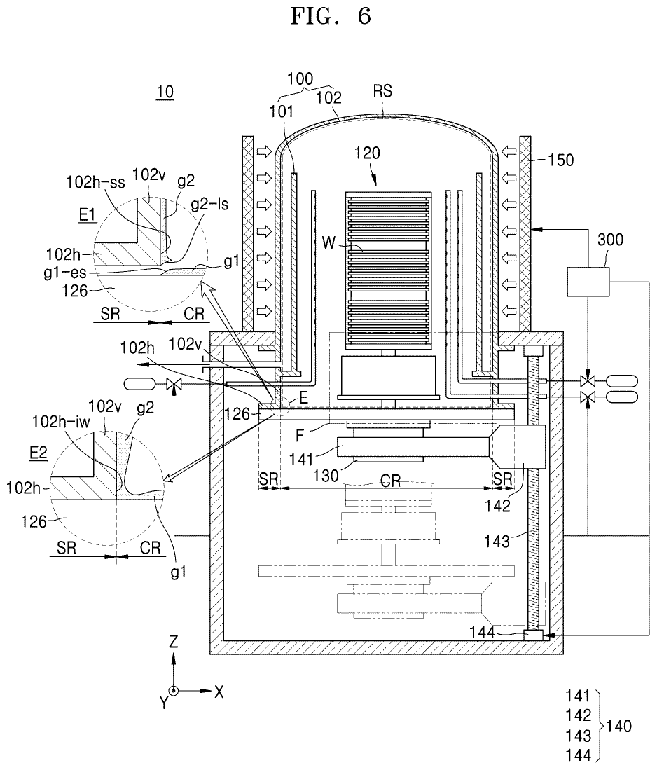

In the annealing mode, the controller 300 may control the vertical driving device 140 such that the boat 120 loaded with the substrate W is introduced into the reaction space RS. The substrate W may be supported by the support structure 123 of the boat 120, and the substrate W may directly contact the first gettering layer on the support structure 123. When the boat 120 loaded with the substrate W is introduced into the reaction space RS, the controller 300 may control the heating device 150 such that the reaction space RS is maintained at a temperature of 500 °C or higher from several hours to dozens of hours. By the heating by the heating device 150, impurities included in the substrate W may be extracted to the first gettering layer and the second gettering layer. The operation of the substrate processing apparatus 10 in the annealing mode will be described in detail in the description of FIG. 6 below.

Next, in operation S1300, the substrate processing apparatus 10 may operate in the cleaning mode. In detail, the substrate processing apparatus 10 may etch a gettering layer containing impurities in the cleaning mode.

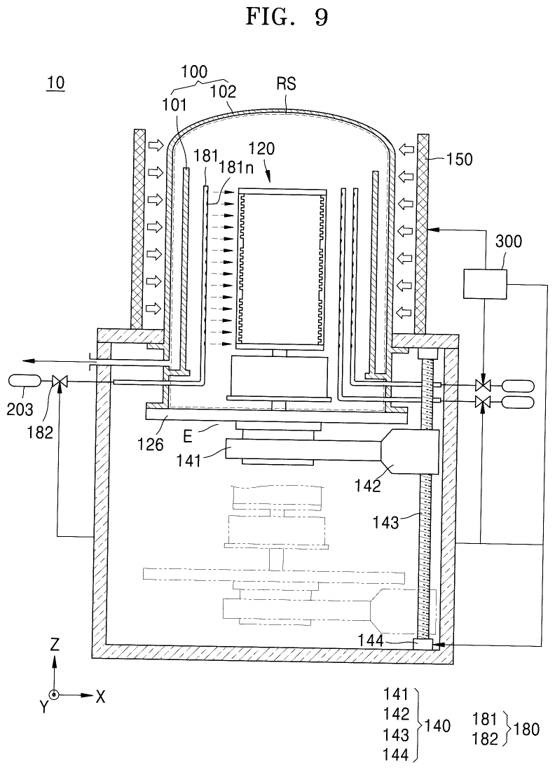

In the cleaning mode, the controller 300 may control the vertical driving device 140 such that the boat 120 without the substrate W loaded thereon is introduced into the reaction space RS. When the boat 120 without the substrate W loaded thereon is introduced into the reaction space RS, the controller 300 may control the cleaning gas supply device 180 such that the cleaning gas is introduced into the reaction space RS. The cleaning gas may remove the first gettering layer and the second gettering layer from the surface of the boat 120 and the surface of the tube 100 through a chemical reaction with the first gettering layer and the second gettering layer. Reaction byproducts generated through the chemical reaction may be discharged to the outside through the exhaust port 190. The operation of the substrate processing apparatus 10 in the cleaning mode will be described in detail in the description of FIG. 9 below.

Although FIG. 2 shows operations S1100, S1200, and S1300 only, various types of operations may be performed between the steps, such as an operation for loading the substrate W onto the boat 120 may be performed between operations S1100 and S1200, and an operation for unloading the substrate W from the boat 120 may be performed between operations S1200 and S1300.

FIG. 3 is a cross-sectional view of the substrate processing apparatus 10 according to embodiments. Referring to FIG. 3, in the gettering layer coating mode of the substrate processing apparatus 10, the controller 300 may control the gettering source gas supply device GS such that the gettering source gas is supplied to the reaction space RS. Also, the controller 300 may control the heating device 150 such that the reaction space RS is heated to form a gettering layer. As the gettering source gas is supplied to the reaction space RS and the reaction space RS is heated, a gettering layer may be deposited, by the gettering source gas, on the surfaces of the tube 100 and the boat 120.

In the gettering layer coating mode, a second gettering layer g2 may be formed on a second coating region of the tube 100. Here, the second coating region of the tube 100 may include, from among the entire surfaces of the tube 100, a surface inside the reaction space RS and a surface in contact with the reaction space RS. When the operation of the substrate processing apparatus 10 in the gettering layer coating mode is completed, the second gettering layer g2 may entirely cover the second coating region of the tube 100.

In the gettering layer coating mode, the second gettering layer g2 may be formed on surfaces of the first tube 101. The first tube 101 may include a vertical portion 101v and a horizontal portion 101h. The vertical portion 101v of the first tube 101 may have a structure extending upward from the horizontal portion 101h, and the horizontal portion 101h of the first tube 101 may have a structure extending horizontally and connected to the lower end of the vertical portion 101v.

The surfaces of the first tube 101 may include an inner surface 101is and an outer surface 101os of the vertical portion 101v, and a lower surface 101h-ls and an upper surface 101h-us of the horizontal portion 101h. The inner surface 101is and the outer surface 101os of the vertical portion 101v and the lower surface 101h-ls and the upper surface 101h-us of the horizontal portion 101h may be arranged inside the reaction space RS. The second gettering layer g2 may entirely cover the inner surface 101is and the outer surface 101os of the vertical portion 101v and the lower surface 101h-ls and the upper surface 101h-us of the horizontal portion 101h. Here, the inner surface 101is of the vertical portion 101v may mean a surface of the vertical portion 101v that faces the boat 120 or is positioned relatively adjacent to the boat 120, and the outer surface 101os of the vertical portion 101v may mean a surface of the vertical portion 101v that faces the second tube 102 or is positioned relatively adjacent to the second tube 102. Also, the lower surface 101h-ls of the horizontal portion 101h may mean a surface that faces the lid member 126 or is positioned at the lowest vertical level from among the surfaces of the horizontal portion 101h, and the upper surface 101h-us of the horizontal portion 101h may mean a surface that is connected to the inner surface 101is and outer surface 101os of the vertical portion 101v or is positioned at the highest vertical level from among the surfaces of the horizontal portion 101h.

For example, referring to the enlarged view A of a region A, which is a portion of the first tube 101, the second gettering layer g2 may cover the inner surface 101is and the outer surface 101os of the vertical portion 101v and the lower surface 101h-ls and the upper surface 101h-us of the horizontal portion 101h. As shown in the enlarged view A of the region A, the thickness of the second gettering layer g2 may not be constant in a corner region of the first tube 101. Here, the corner region of the first tube 101 may refer to a region where the vertical portion 101v of the first tube 101 and the horizontal portion 101h of the first tube 101 are connected to one another, and the corner region of the first tube 101 may include a region where the inner surface 101is and the upper surface 101h-us are connected to one another and a region where the outer surface 101os and the upper surface 101h-us are connected to one another. As the thickness of the second gettering layer g2 in the corner region is uneven, the second gettering layer g2 covering the upper surface 101h-us of the horizontal portion 101h and the second gettering layer g2 covering the inner surface 101is or the outer surface 101os of the vertical portion 101v may be connected to one another at an angle less than 90 degrees. However, depending on the shape of the corner region, the second gettering layer g2 on the corner region may be formed to have a uniform thickness. For example, the corner region may have a rounded surface, and the second gettering layer g2 may be formed to have a uniform thickness along the rounded surface.

Referring to an enlarged view B of a region B, which is a portion of the first tube 101, the second gettering layer g2 may entirely cover the inner surface 101is and the outer surface 101os of the vertical portion 101v. As shown in the enlarged view B of the region B, the thickness of the second gettering layer g2 on the inner surface 101is and the outer surface 101os may be substantially uniform. According to some embodiments, the second gettering layer g2 on the inner surface 101is may have a relatively greater thickness than the second gettering layer g2 on the outer surface 101os.

In the gettering layer coating mode, the second gettering layer g2 may be formed on surfaces of the second tube 102. The surfaces of the second tube 102 may include an inner surface 102is and an outer surface 102os. Here, the inner surface 102is of the second tube 102 may be a surface of the second tube 102 that contacts the reaction space RS and may be a surface facing the boat 120. The second gettering layer g2 may completely cover the inner surface 102is of the second tube 102.

Referring to an enlarged view C of a region C, which is a portion of the second tube 102, the second gettering layer g2 may be placed on the inner surface 102is of the second tube 102. The upper portion of the second tube 102 may have a structure of a dome-like shape convex in the upward direction, and the second gettering layer g2 may also have a dome-like shape convex in the upward direction along the inner surface 102is of the second tube 102.

In the above descriptions, an example is described, in which the second gettering layer g2 may be formed on the surface of the tube 100 inside the reaction space RS and on the surface of the tube 100 in contact with the reaction space RS through the enlarged view A of the region A, the enlarged view B of the region B, and the enlarged view C of the region C. However, regions A, B, and C are merely examples for convenience of explanation, and the second gettering layer g2 may cover not only regions A, B, and C of the tube 100, but also the entire second coating region of the tube 100.

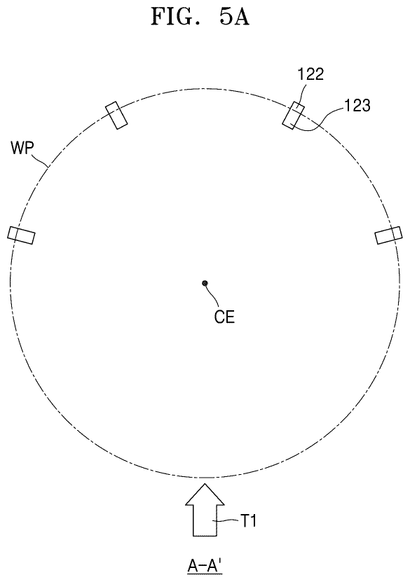

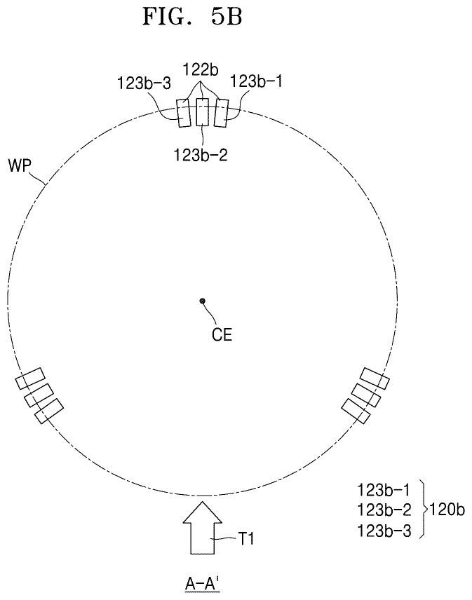

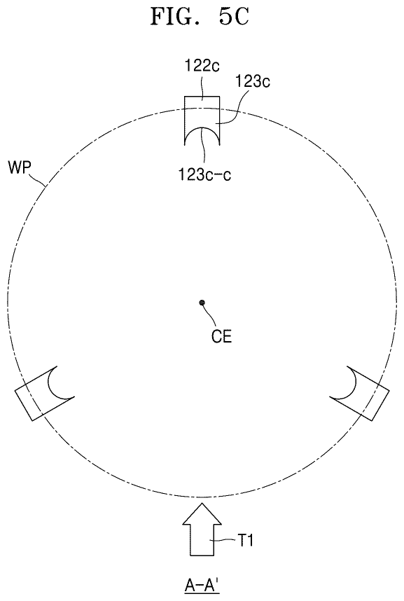

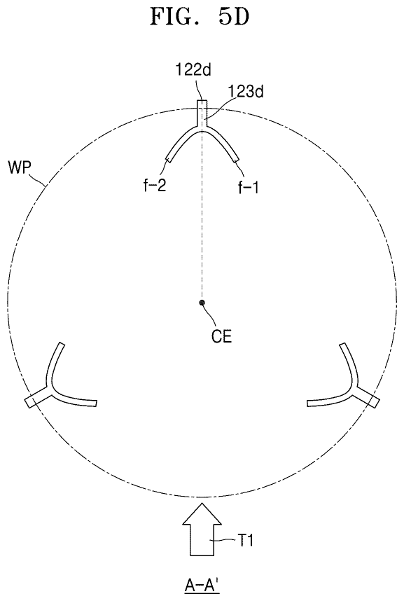

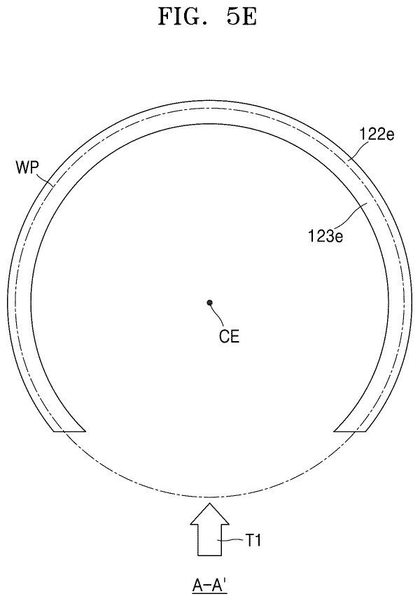

In the gettering layer coating mode, the boat 120 without the substrate W loaded thereon may be introduced into the reaction space RS, and a gettering layer may also be formed on the surface of the boat 120. Detailed descriptions thereof will be given below in the description of FIGS. 4 to 5E.

FIG. 4 is a perspective view of the boat 120 according to embodiments. Referring to FIG. 4, in the gettering layer coating mode, a first gettering layer g1 may be formed on a first coating region of the boat 120. When the operation of the substrate processing apparatus 10 in the gettering layer coating mode is completed, the first gettering layer g1 may entirely cover the first coating region of the boat 120. Here, the first coating region of the boat 120 may include a surface inside the reaction space RS and a surface in contact with the reaction space RS from among the entire surfaces of the boat 120.

For example, in the gettering layer coating mode, the top plate 121, the rod 122, the support structure 123, the bottom plate 124, and the support 125 are arranged inside the reaction space RS, and thus the first gettering layer g1 may cover surfaces of the top plate 121, the rod 122, the support structure 123, the bottom plate 124, and the support 125. On the other hand, from among surfaces of the lid member 126, the upper surface of the lid member 126 is in contact with the reaction space RS, while a bottom surface of the lid member 126 is not in contact with the reaction space RS, and thus the first gettering layer g1 may be disposed on the upper surface of the lid member 126 and not on the bottom surface of the lid member 126. However, according to some embodiments, the first gettering layer g1 may be disposed on some regions of the bottom surface of the lid member 126.

As shown in FIG. 4, the support structure 123 has a slot-like shape for supporting the substrate W and may have a shape that protrudes horizontally from the rod 122 toward the central axis of the boat 120. Referring to an enlarged view D1 of a region D, which is a portion of the boat 120, the first gettering layer g1 may be placed on the surface of the support structure 123 and the surface of the rod 122.

As shown in the enlarged view D1 of the region D, the first gettering layer g1 may entirely cover an upper surface 123us, a bottom surface 1231s, and sidewall surfaces 123ss of the support structure 123. The thickness of the first gettering layer g1 covering the surface of the support structure 123 and the surface of the rod 122 may not be uniform in the corner region. For example, the first gettering layer g1 may include a concave portion g1-r and a convex portion g1-c. The concave portion g1-r of the first gettering layer g1 may be arranged (or formed) in a corner region where the upper surface 123us and the sidewall surfaces 123ss of the support structure 123 are connected to one another, and in a corner region where the bottom surface 1231s and the sidewall surfaces 123ss are connected to one another. Also, the concave portion g1-r of the first gettering layer g1 may be arranged (or formed) in a corner region where the upper surface 123us of the support structure 123 and the surface of the rod 122 are connected to one another, and in a corner region where the bottom surface 1231s of the support structure 123 and the surface of the rod 122 are connected to one another. However, depending on the shape of the corner region, the thickness of the first gettering layer g1 covering the surface of the support structure 123 and the surface of the rod 122 may be uniform throughout. According to embodiments, the corner region may have a rounded surface, and the first gettering layer g1 may be formed with a uniform thickness along the rounded surface without including the concave portion g1-r and the convex portion g1-c.

According to embodiments, as shown in an enlarged view D2 of the region D, which is a portion of the boat 120, the support structure 123 may include a plurality of protrusions 123p. The plurality of protrusions 123p may be arranged on at least one of the upper surface 123us, the bottom surface 1231s, and the sidewall surfaces 123ss of the support structure 123. The enlarged view D2 of the region D shows that the plurality of protrusions 123p are arranged on the upper surface 123us, the bottom surface 1231s, and the sidewall surfaces 123ss of the support structure 123, but this is merely an example, and the plurality of protrusions 123p may be arranged only on the upper surface 123us. The plurality of protrusions 123p may be arranged to protrude upward from the upper surface 123us. The first gettering layer g1 may be disposed on surfaces of the plurality of protrusions 123p. The first gettering layer g1 may cover the entire surfaces of the plurality of protrusions 123p.

As the support structure 123 includes the plurality of protrusions 123p, the surface area of the support structure 123 may increase. As the surface area increases, the total amount of the first gettering layer g1 formed (or deposited) on the surface of the support structure 123 may increase. Also, as the total amount of the first gettering layer g1 formed on the surface of the support structure 123 increases, in the annealing mode described below, extraction (or diffusion) of impurities included in the substrate W to the first gettering layer g1 may be performed more quickly.

As described above with reference to FIGS. 3 and 4, when the operation of the substrate processing apparatus 10 in the gettering layer coating mode is completed, the first gettering layer g1 may be formed on the first coating region of the boat 120 and the second gettering layer g2 may be formed on the second coating region of the tube 100. The thickness of the first gettering layer g1 from the first coating region may be 10 nm or greater, and the thickness of the second gettering layer g2 from the second coating region may also be 10 nm or greater. As the first gettering layer g1 and the second gettering layer g2 are each formed to have a thickness of 10 nm or greater, diffusion of impurities from the substrate W to the first gettering layer g1 and the second gettering layer g2 may be performed more effectively.

The substrate processing apparatus 10 may efficiently perform a gettering process on the substrate W by forming the first gettering layer g1 and the second gettering layer g2 each having a thickness of 10 nm or greater on the first coating region of the boat 120 and the second coating region of the tube 100, respectively, without forming a gettering layer directly on the substrate W. Also, in the cleaning mode described below, since each of the first gettering layer g1 and the second gettering layer g2 has a thickness of 10 nm or greater, surface damage of the tube 100 and surface damage of the boat 120 caused by the cleaning gas may be suppressed as much as possible.

FIGS. 5A to 5E are cross-sectional views of the boat 120 according to embodiments. FIGS. 5A to 5E are each a cross-sectional view of the boat 120 taken along a line A-A′ of FIG. 4. Here, FIGS. 5A to 5E illustrate cross-sections of the boat 120 according to different embodiments.

FIG. 5A is a horizontal cross-sectional view of the boat 120 shown in FIG. 4. FIG. 5A is a cross-sectional view of the boat 120 including four rods 122 and slot-like support structures 123 respectively protruding from the four rods 122 in horizontal directions. The substrate W may be fed into a substrate feeding position WP in a substrate feeding direction T1. Although FIGS. 4 and 5A only show that the boat 120 may include four rods 122, this is merely an example. The number of rods 122 may vary, e.g., 1, 2, 3, 5 or more.

FIG. 5B shows a horizontal cross-section of the boat 120 according to embodiments different from embodiments shown in FIG. 5A. Referring to FIG. 5B, the boat 120 may include nine rods 122b and three support structure pairs 123b. The three support structure pairs 123b may be arranged at equal intervals along the circumference of the substrate feeding position WP.

The support structure pairs 123b may include a first support structure 123b-1, a second support structure 123b-2, and a third support structure 123b-3. The first support structure 123b-1, the second support structure 123b-2, and the third support structure 123b-3 may each protrude from the rods 122b toward a central axis CE of the boat 120 in the horizontal directions and have a slot-like shape. The first gettering layer g1 may cover the surfaces of three support structures 123b-1, 123b-2, and 123b-3. FIG. 5B shows that the support structure pairs 123b may include the three support structures 123b-1, 123b-2, and 123b-3, but this is merely an example. The support structure pairs 123b may include two support structures or four or more support structures. Also, although FIG. 5B only shows that the boat 120 may include three support structure pairs 123b, this is merely an example, and the boat 120 may include two support structure pairs 123b and four or more support structure pairs 123b.

FIG. 5C shows a horizontal cross-section of the boat 120 according to embodiments. Referring to FIG. 5C, the boat 120 may include three rods 122c and three support structures 123c respectively protruding from the three rods 122c in horizontal directions.

The support structures 123c may each include a curved portion 123c-c. The curved portion 123c-c may be placed on one end of the support structure 123c. Although FIG. 5C only shows that the curved portion 123c-c has a concave shape in the direction toward the central axis CE, the curved portion 123c-c may also be implemented in a convex shape in the direction toward the central axis CE. As one end of the support structure 123c is formed as the curved portion 123c-c, the surface area of the support structure 123c may increase, and thus the total amount of the first gettering layer g1 formed on the surface of the support structure 123c may increase. Also, an area in which the support structure 123c and the substrate W overlap in the vertical direction may increase. Although FIG. 5C only shows that one end of the support structure 123c facing the central axis CE of the boat 120 may be formed as the curved portion 123c-c, it is merely an example. Both sidewalls of the support structure 123c may also be implemented in a curved shape.

FIG. 5D shows a horizontal cross-section of the boat 120 according to embodiments. Referring to FIG. 5D, the boat 120 may include three rods 122d and three support structures 123d respectively protruding from the three rods 122d in horizontal directions.

A support structure 123d may include a first finger f-1 and a second finger f-2. The first finger f-1 and the second finger f-2 may have structures symmetrical to one another and may protrude horizontally toward the central axis CE of the boat 120. In detail, the first finger f-1 and the second finger f-2 may have a structure that is symmetrical to one another around a straight line connecting a rod 122d the central axis CE of the boat 120. As the support structure 123d includes the first finger f-1 and the second finger f-2, the surface area of the support structure 123d may increase. Therefore, the total amount of the first gettering layer g1 formed on the surface of the support structure 123d may increase. Also, an area in which the support structure 123d and the substrate W overlap in the vertical direction may also increase. Although FIG. 5D only shows that the support structure 123d includes two fingers, i.e., the first finger f-1 and the second finger f-2, it is to be understood that the support structure 123d may include three or more fingers that protrude horizontally toward the central axis CE and have a symmetrical structure with respect to one another. According to some embodiments, a plurality of fingers may not be symmetrical to one another.

FIG. 5E shows a horizontal cross-section of the boat 120 according to embodiments. Referring to FIG. 5E, the boat 120 may include one rod 122e and a support structure 123e protruding from the one rod 122e in a horizontal direction toward the central axis CE.

The rod 122e may have a circular ring-like structure that extends along the circumference of the substrate feeding position WP. The circular ring-like structure of the rod 122e may be a structure in which a portion of a circular ring is cut off. In other words, the circular ring-like structure of the rod 122e may have a central angle of less than 360 degrees. For example, the rod 122e may have a circular ring-like structure having the central axis CE as the center of the circle and a central angle of 210 degrees with respect to the central axis CE. The support structure 123e may also have a circular ring-like structure. The central angle of the circular ring-like structure of the support structure 123e may be the same as the central angle of the rod 122e. For example, the central angle of the circular ring-like structure of the support structure 123e may be 210 degrees. As the support structure 123e has a circular ring-like structure with a central angle exceeding 180 degrees, the total amount of the first gettering layer g1 formed on the surface of the support structure 123e may increase. Also, an area in which the support structure 123e and the substrate W overlap in the vertical direction may also increase.

Support structures shown in each of FIGS. 5A to 5E have large surface areas and are merely example structures for securing large overlapping areas in the vertical direction with the substrate W, and the support structures of the inventive concept are not limited to the support structures shown in FIGS. 5A to 5E. The boat 120 according to one or more embodiments may include various types of support structures to secure a wide overlapping area in the vertical direction with the substrate W and to increase the surface area on which the first gettering layer g1 may be formed. The boat 120 may have a wide overlapping area in the vertical direction with the substrate W and include the support structure 123 having a wide surface area, thereby increasing the contact area between the substrate W and the first gettering layer g1, and thus extraction of impurities from the substrate W to the first gettering layer g1 may be performed more effectively.

FIG. 6 is a cross-sectional view of the substrate processing apparatus 10 according to embodiments. Referring to FIG. 6, in the annealing mode of the substrate processing apparatus 10, the controller 300 may control the heating device 150 to heat the reaction space RS to maintain the reaction space RS at a temperature of 500 °C or higher from several hours to dozens of hours.

As the reaction space RS is heated to a temperature of 500 °C or higher, impurities included in the substrate W may be extracted into the first gettering layer g1 and the second gettering layer g2.

In the annealing mode, the boat 120 loaded with at least one substrate W may be introduced into the reaction space RS. In detail, after the operation of the substrate processing apparatus 10 in the gettering layer coating mode is completed, the boat 120 may be moved out of the reaction space RS. The boat 120 may be moved out of the reaction space RS by the vertical driving device 140. Next, at least one substrate W may be loaded onto the boat 120, and the at least one substrate W may be placed on the first gettering layer g1 covering the surface of the support structure 123 of the boat 120. Once the loading of the at least one substrate W is completed, operations of the substrate processing apparatus 10 in the annealing mode may be performed. Therefore, in the annealing mode, the first gettering layer g1 may already be formed in the first coating region of the boat 120, and the second gettering layer g2 may already be formed in the second coating region of the tube 100.

According to some embodiments, the first gettering layer g1 and the second gettering layer g2 may include amorphous silicon (Si). Also, the first gettering layer g1 and the second gettering layer g2 may further include at least one of phosphorus (P), oxygen (O), carbon (C), and nitrogen (N). For example, the first gettering layer g1 and the second gettering layer g2 may be phosphorus-doped silicon or phosphorus-doped silicon oxide. Here, when the first gettering layer g1 and the second gettering layer g2 include phosphorus-doped silicon, the atomic concentration of phosphorus (P) constituting the first gettering layer g1 and the second gettering layer g2 may be 3 at % (atomic percent) or greater based on the total number of atoms. Also, when the first gettering layer g1 and the second gettering layer g2 include phosphorus-doped silicon oxide, the atomic concentration of phosphorus (P) constituting the first gettering layer g1 and the second gettering layer g2 may be 1 at % or greater.

In another example, the first gettering layer g1 and the second gettering layer g2 may include silicon carbide (SiC), silicon nitride (SiN), silicon oxide (SiO), or silicon carbonitride (SiCN). In this case, the atomic concentration of carbon (C), nitrogen (N), and oxygen (O) constituting the first gettering layer g1 and the second gettering layer g2 may each be 2 at % or greater.

Since the first gettering layer g1 and the second gettering layer g2 include a material such as silicon carbide containing 2 at % or more of carbon or silicon oxide containing 2 at % or more of oxygen, the first gettering layer g1 and the second gettering layer g2 may effectively extract/capture transition metals included in the substrate W. However, the description above is merely an example of materials constituting the first gettering layer g1 and the second gettering layer g2, and it is obvious that the first gettering layer g1 and the second gettering layer g2 may further include various materials capable of effectively extracting/capturing transition metals.

In the annealing mode, the boat 120 loaded with at least one substrate W may move upward toward the reaction space RS. As the boat 120 moves upward, the second tube 102 and the lid member 126 of the boat 120 may be connected to one another. In detail, the second tube 102 may include a vertical portion 102v extending in a vertical direction and a horizontal portion 102h connected to the lowermost end of the vertical portion 102v and extending in a horizontal direction. The horizontal portion 102h of the second tube 102 may be connected to the upper surface of the lid member 126. The upper surface of the lid member 126 may include a central region CR and a sealing region SR. The sealing region SR may mean a region connected to the horizontal portion 102h from among the entire regions of the upper surface of the lid member 126. A sealing member (e.g., an O-ring) for combining the lid member 126 with the horizontal portion 102h may be placed in the sealing region SR. The central region CR is a region excluding the sealing region SR from among the entire regions of the upper surface of the lid member 126, and may mean a region in contact with the reaction space RS.

Referring to an enlarged view E1 of a region, which is a portion of the second tube 102, before the horizontal portion 102h of the second tube 102 and the upper surface of the lid member 126 are connected to one another, the first gettering layer g1 and the second gettering layer g2 may be separated from one another. The first gettering layer g1 may be disposed only on the central region CR, and the first gettering layer g1 may not be disposed on the sealing region SR. Also, the second gettering layer g2 may be disposed only on sidewall surfaces 102h-s of the horizontal portion 102h, and may not be disposed on the bottom surface or the upper surface of the horizontal portion 102h. Here, the sidewall surfaces 102h-ss of the horizontal portion 102h refers to surfaces in contact with the reaction space RS.

As shown in an enlarged view E1 of the region E, an edge surface g1-es of the first gettering layer g1 may have a surface having a shape substantially the same as that of a lower surface g2-ls of the second gettering layer g2. Here, the edge surface g1-es of the first gettering layer g1 may refer to the surface of the first gettering layer g1 that exists on the region closest to the sealing region SR, in the central region CR. Also, the lower surface g2-ls of the second gettering layer g2 may mean the lowermost surface from among surfaces of the second gettering layer g2 formed on the sidewall surfaces 102h-ss of the horizontal portion 102h. The first gettering layer g1 and the second gettering layer g2 are gettering layers formed integrally in the gettering layer coating mode. Therefore, even when the first gettering layer g1 and the second gettering layer g2 are physically separated by the vertical driving of the lid member 126 by the vertical driving device 140, the edge surface g1-es of the first gettering layer g1 and the lower surface g2-ls of the second gettering layer g2 have surfaces of the same shape, and the edge surface g1-es of the first gettering layer g1 and the lower surface g2-ls of the second gettering layer g2 may match with one another.

However, according to some embodiments, when a portion of the first gettering layer g1 and/or a portion of the second gettering layer g2 is cut or damaged, the edge surface g1-es of the first gettering layer g1 and the lower surface g2-ls of the second gettering layer g2 may not match with one another.

Referring to an enlarged view E2 of the region E, which is a portion of the second tube 102, by driving the lid member 126 upward by the vertical driving device 140, the sealing region SR of the lid member 126 and the horizontal portion 102h may be connected to one another. The first gettering layer g1 on the upper surface of the lid member 126 and the second gettering layer g2 on sidewall surfaces 102h-iw of the horizontal portion 102h may be connected to one another. In detail, the first gettering layer g1 and the second gettering layer g2 may be exposed to a high temperature environment in the annealing mode, and the first gettering layer g1 and the second gettering layer g2 may be connected and bonded to one another.

According to some embodiments, in the annealing mode, the reaction space RS may be maintained at a high pressure. The pressure in the reaction space RS may be from 10 atm to 100 atm. Also, the reaction space RS may be filled with an annealing gas (or a heat treatment gas). For example, the annealing gas may be at least one of high pressure hydrogen gas (H₂), high pressure deuterium gas (D₂), and high pressure nitrogen gas (N₂). In detail, in the annealing mode, the reaction space RS may be filled with hydrogen gas from about 10 atm to about 100 atm. In another example, the reaction space RS may be filled with a mixed gas from about 10 atm to about 100 atm. Here, the mixed gas may refer to a mixed gas of hydrogen gas and nitrogen gas, or a mixed gas of deuterium gas and nitrogen gas. In the annealing mode, the hydrogen gas, the deuterium gas, or the nitrogen gas may be supplied to the reaction space RS by the first gas supply device 160, the second gas supply device 170, or the cleaning gas supply device 180. The description given above only explains that the annealing gas is at least one of hydrogen gas, deuterium gas, and nitrogen gas, but it is merely an example. The reaction space RS in the annealing mode may be filled with high-pressure gases other than hydrogen gas, deuterium gas, or nitrogen gas.

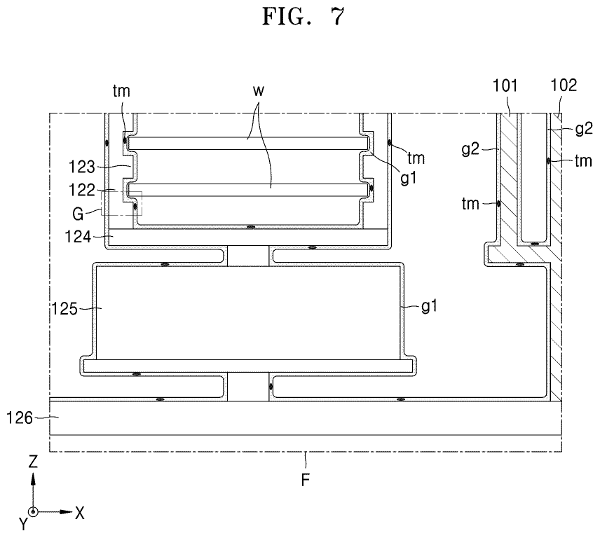

In the annealing mode, a transition metal included in the at least one substrate W may be extracted into the first gettering layer g1, and the transition metal extracted into the first gettering layer g1 may move to the second gettering layer g2 connected to the first gettering layer g1. When the operation of the substrate processing apparatus 10 in the annealing mode is completed, the transition metal present in the substrate W may be extracted (or diffused) into the second gettering layer g2 connected to the first gettering layer g1. For example, the first gettering layer g1 and the second gettering layer g2 may include nickel (Ni). The operation for extracting a transition metal from the substrate W to the first gettering layer g1 and the second gettering layer g2 will be described below in detail in the description of FIG. 7.

FIG. 7 is an enlarged cross-sectional view F of the substrate processing apparatus 10 according to embodiments. FIG. 7 is an enlarged cross-sectional view of a region F of the substrate processing apparatus 10 of FIG. 6. Referring to FIG. 7, in the annealing mode of the substrate processing apparatus 10, the substrate W may be placed on the first gettering layer g1, and the first gettering layer g1 and the second gettering layer g2 may include a transition metal tm.

In the annealing mode, the first gettering layer g1 may cover the surface of the rod 122 and the surface of the support structure 123. Also, the first gettering layer g1 may cover the surface of the bottom plate 124, the surface of the support 125, and the upper surface of the lid member 126. The first gettering layer g1 may be an integral material layer continuously formed along surfaces of the rod 122, the support structure 123, the bottom plate 124, the support 125, and the lid member 126. Also, the second gettering layer g2 may cover the surfaces of the first tube 101 and the second tube 102. As described above in the description of FIG. 6, the second gettering layer g2 may be connected to the first gettering layer g1.

In the annealing mode, the transition metal tm may be extracted from the substrate W to the first gettering layer g1 and move from the first gettering layer glto the second gettering layer g2. Here, the transition metal tm may be a metal silicide. For example, the transition metal tm may be nickel silicide (NiSi). However, the transition metal tm may include various types of metal silicides, such as tungsten silicide (WSi), cobalt silicide (CoSi), etc., in addition to nickel silicide (NiSi).

As shown in FIG. 7, according to some embodiments, a portion of the bottom surface of the substrate W may be in contact with the first gettering layer g1. Also, a portion of the upper surface of the substrate W and a portion of the sidewall surfaces of the substrate W may also be in contact with the first gettering layer g1. As the contact area between the substrate W and the first gettering layer g1 is sufficiently secured, diffusion (or extraction) of the transition metal tm from the substrate W to the first gettering layer g1 may be actively performed. However, according to some embodiments, the upper surface of the substrate W and the sidewall surfaces of the substrate W may not be in contact with the first gettering layer g1.

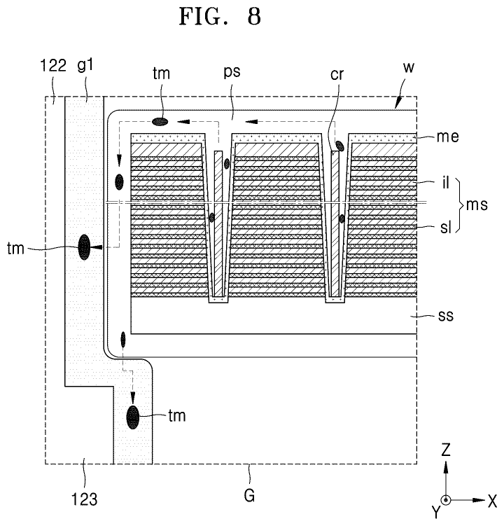

According to some embodiments, the substrate W may be a wafer including a polycrystalline silicon layer. When metal-induced crystallization (MIC) or metal-induced lateral crystallization (MILC) is performed on a wafer to form a polycrystalline silicon layer, the transition metal tm may remain in the polycrystalline silicon layer of the wafer. An operation for extracting the transition metal tm from a polycrystalline silicon layer will be described in detail in the description of FIG. 8 below.

FIG. 8 is an enlarged cross-sectional view G of the substrate processing apparatus 10 according to embodiments. FIG. 8 is an enlarged cross-sectional view of a region G of FIG. 7. Referring to FIG. 8, the substrate W may include a support substrate ss, a mold stack ms, a memory layer me, and a polycrystalline silicon layer ps.

For example, the substrate W may be a wafer for manufacturing a 3D NAND flash memory device. The mold stack ms may include a plurality of insulation layers il and a plurality of sacrificial layers sl alternately stacked in a vertical direction, and the mold stack ms may be disposed on the support substrate ss. The memory layer me may be disposed on the topmost insulation layer il and may be disposed in a channel hole that penetrates through the mold stack ms in the vertical direction. In the channel hole, the memory layer me may be placed (or formed) to cover the sidewalls of the mold stack ms and a portion of the support substrate ss. A core layer cr may be disposed at the center of the channel hole and disposed on the memory layer me.

The polycrystalline silicon layer ps may surround the support substrate ss, the mold stack ms, the memory layer me, and the core layer cr. In detail, the polycrystalline silicon layer ps may entirely surround the bottom surface and the sidewall surfaces of the support substrate ss, and entirely surround the outermost sidewall surfaces of the mold stack ms and the upper surface of the mold stack ms. As described above, the polycrystalline silicon layer ps may be a layer formed through metal induced crystallization or metal induced lateral crystallization, and may include the transition metal tm.

In the annealing mode of the substrate processing apparatus 10, the polycrystalline silicon layer ps may be placed on the first gettering layer g1. A portion of the bottom surface of the polycrystalline silicon layer ps may be in contact with the first gettering layer g1. According to some embodiments, at least one of sidewall surfaces of the polycrystalline silicon layer ps and the upper surface of the polycrystalline silicon layer ps may be in contact with the first gettering layer g1. In the annealing mode, the reaction space RS is maintained at a high temperature of 500 °C or higher, and thus the polycrystalline silicon layer ps and the first gettering layer g1 may be connected (or bonded) to one another.

The transition metal tm may diffuse (or be extracted) from the polycrystalline silicon layer ps into the first gettering layer g1. The transition metal tm may migrate through a contact surface between the polycrystalline silicon layer ps and the first gettering layer g1. For example, the bottom surface of the polycrystalline silicon layer ps may be in contact with the first gettering layer g1, and, in this case, the transition metal tm may diffuse from the bottom surface of the polycrystalline silicon layer ps toward the first gettering layer g1 in contact with the bottom surface of the polycrystalline silicon layer ps. In another example, the sidewall surface of the polycrystalline silicon layer ps may be in contact with the first gettering layer g1, and, in this case, the transition metal tm may diffuse from the sidewall surface of the polycrystalline silicon layer ps toward the first gettering layer g1 in contact with the sidewall surface of the polycrystalline silicon layer ps.

Returning back to FIG. 6, when the operation of the substrate processing apparatus 10 in the annealing mode is completed, the boat 120 loaded with the at least one substrate W may be moved out of the reaction space RS. Afterwards, the at least one substrate W may be unloaded from the boat 120. During the process of unloading the substrate W, the controller 300 may control the vibration device 130 to apply vibration to the boat 120. Here, the vibration applied to the boat 120 by the vibration device 130 may be used to separate the bond between the polycrystalline silicon layer ps and the first gettering layer g1. According to some embodiments, the material constituting the first gettering layer g1 may remain on the surface of the substrate W unloaded from the boat 120. According to some embodiments, polycrystalline silicon on the first gettering layer g1 may remain on the surface of the boat 120 after the substrate W is unloaded.

After the at least one substrate W is unloaded, operations of the substrate processing apparatus 10 in the cleaning mode may be performed. The cleaning mode will be described in detail in the description of FIG. 9 below.

FIG. 9 is a cross-sectional view of the substrate processing apparatus 10 according to embodiments. Referring to FIG. 9, in the cleaning mode of the substrate processing apparatus 10, the controller 300 may control the cleaning gas supply device 180 such that the cleaning gas is supplied to the reaction space RS. According to a control signal of the controller 300, the cleaning gas valve 182 may be opened, and the cleaning gas may be injected into the reaction space RS through a cleaning gas nozzle 181n of the cleaning gas supply pipe 181. Also, the controller 300 may control the heating device 150 to heat the reaction space RS. As the cleaning gas is introduced into the reaction space RS, the first gettering layer g1 and the second gettering layer g2 including impurities such as the transition metal tm may be etched by the cleaning gas.

In the cleaning mode, the boat 120 from which the at least one substrate W is unloaded may be introduced into the reaction space RS. The introduction of the boat 120 into the reaction space RS may be performed by the vertical driving device 140. The cleaning mode is performed after the operation of the substrate processing apparatus 10 in the annealing mode, and thus the second gettering layer g2 may already be formed on the surface of the tube 100, and the first gettering layer g1 may already be formed on the surface of the boat 120. Also, the first gettering layer g1 and the second gettering layer g2 may include impurities such as the transition metal tm, and the impurities may be materials extracted from the at least one substrate W. For example, the first gettering layer g1 and the second gettering layer g2 may include nickel (Ni).

In the cleaning mode, the substrate processing apparatus 10 may remove the first gettering layer g1 and the second gettering layer g2 containing impurities through a vapor etching process based on the cleaning gas. As describe above with reference to FIG. 1, the cleaning gas may include at least one of Cl₂, HBr, F₂, and CIF₃.

When the operation of the substrate processing apparatus 10 in the cleaning mode is completed, the first gettering layer g1 and the second gettering layer g2 may be removed, and thus the surfaces of the tube 100 and the boat 120 may be exposed to the reaction space RS. Preferably, the first gettering layer g1 and the second gettering layer g2 may be completely removed. However, according to some embodiments, a portion of the first gettering layer g1 and a portion of the second gettering layer g2 may remain on the surface of the tube 100 and the surface of the boat 120. According to some embodiments, after the operation of the substrate processing apparatus 10 in the cleaning mode is completed, the substrate processing apparatus 10 may operate again in the gettering layer coating mode to perform an impurity extraction process for a new substrate W.

As described above, the substrate processing apparatus 10 may operate in the order of the gettering layer coating mode, the annealing mode, and the cleaning mode. By operating in the gettering layer coating mode, the annealing mode, and the cleaning mode, the substrate processing apparatus 10 may efficiently perform an impurity extraction process for the substrate W without forming various types of material layers on the substrate W or etching various types of material layers formed on the substrate W. Therefore, the substrate processing apparatus 10 may simplify the overall flow of a semiconductor manufacturing process and reduce the cost of the semiconductor manufacturing process.

While the inventive concept has been particularly shown and described with reference to embodiments thereof, it will be understood that various changes in form and details may be made therein without departing from the spirit and scope of the following claims.

What is claimed is:

1. A substrate processing apparatus comprising:
a boat configured to accommodate at least one substrate;
a tube configured to define a reaction space of the at least one substrate;
a vertical driving device configured to drive the boat in a vertical direction;
a heating device surrounding the tube and configured to heat the reaction space;
a gettering source gas supply device configured to supply a gettering source gas to the reaction space;
a cleaning gas supply device configured to supply a cleaning gas to the reaction space;
a first gettering layer on a surface of the boat; and
a second gettering layer on a surface of the tube,
wherein:
the first gettering layer and the second gettering layer comprise silicon (Si), and
the first gettering layer and the second gettering layer further comprise at least one of phosphorus (P), oxygen (O), carbon (C), and nitrogen (N).

2. The substrate processing apparatus of claim 1, wherein, in an annealing mode by
the heating device,
the first gettering layer covers a coating region of the surface of the boat, and the first coating region comprises:
from among entire surfaces of the boat, a surface inside the reaction space; and
from among the entire surfaces of the boat, a surface in contact with the reaction space, and
the annealing mode is an operation mode for extracting a transition metal from the at least one substrate to the first gettering layer and the second gettering layer.

3. The substrate processing apparatus of claim 2, wherein, in the annealing mode, the second gettering layer covers a second coating region of the surface of the tube, and the second coating region comprises:
from among entire surfaces of the tube, a surface inside the reaction space; and
from among the entire surfaces of the tube, a surface in contact with the reaction space.

4. The substrate processing apparatus of claim 3, wherein, in the annealing mode:
a thickness of the first gettering layer from the first coating region is 10 nm or greater, and a thickness of the second gettering layer from the second coating region is 10 nm or greater.

5. The substrate processing apparatus of claim 2, wherein, in the annealing mode, at least one of the first gettering layer and the second gettering layer comprises nickel (Ni).

6. The substrate processing apparatus of claim 2, wherein the boat comprises:
at least one rod extending in the vertical direction; and
at least one support structure protruding horizontally from the at least one rod toward a central axis of the boat and supporting the at least one substrate,
wherein, in the annealing mode:
the first gettering layer covers a surface of the at least one support structure and a surface of the at least one rod, and
the at least one substrate is disposed on the first gettering layer.

7. The substrate processing apparatus of claim 6, wherein the at least one support structure comprises a plurality of protrusions protruding from the surface of the at least one support structure.

8. The substrate processing apparatus of claim 6, wherein the tube comprises:
a vertical portion extending in the vertical direction; and
a horizontal portion connected to a lowermost end of the vertical portion and extending in a horizontal direction, and
the boat comprises
a lid member connected to a bottom surface of the horizontal portion, wherein, in the annealing mode,
the first gettering layer on a upper surface of the lid member and the second gettering layer on a sidewall surface of the horizontal portion are connected to one another.

9. The substrate processing apparatus of claim 8, wherein:
the upper surface of the lid member comprises a central region and a sealing region,
in the annealing mode, the first gettering layer is disposed on the central region,
the central region is a region excluding the sealing region from among the entire region of the upper surface of the lid member, and
the sealing region is a region where a bond between the lid member and the horizontal portion is formed.

10. The substrate processing apparatus of claim 1, wherein:
the cleaning gas comprises at least one of chlorine gas (Cl₂), hydrogen bromide gas (HBr), fluorine gas (F₂), and chlorine trifluoride gas (ClF₃),
the boat comprises at least one of silicon oxide (SiO) and silicon nitride (SiN), and
the tube comprises at least one of silicon oxide (SiO) and silicon nitride (SiN).

11. A substrate processing apparatus comprising:
a boat configured to accommodate at least one substrate;
a tube configured to define a reaction space of the at least one substrate;
a heating device surrounding the boat and configured to heat the reaction space;
a gettering source gas supply device configured to supply a gettering source gas to the reaction space; and
a controller configured to control the heating device and the gettering source gas supply device,
wherein:
the controller controls, in a gettering layer coating mode, the gettering source gas supply device to supply the gettering source gas into the reaction space when the boat is introduced into the reaction space,
the controller controls, in an annealing mode, the heating device to heat the reaction space when the boat loaded with the at least one substrate is introduced into the reaction space,
the gettering layer coating mode is an operation mode for forming a first gettering layer covering a surface of the boat and a second gettering layer covering a surface of the tube, and
the annealing mode is an operation mode for extracting a transition metal from the at least one substrate to the first gettering layer and the second gettering layer.

12. The substrate processing apparatus of claim 11, further comprising a vertical driving device configured to drive the boat in a vertical direction,
wherein:
in the gettering layer coating mode, the controller controls the vertical driving device such that the boat, which is not loaded with the at least one substrate, is introduced into the reaction space; and,
when the first gettering layer and the second gettering layer are formed, controls the vertical driving device to move the boat out of the reaction space.

13. The substrate processing apparatus of claim 11, wherein:
a thickness of the first gettering layer from the surface of the boat is 10 nm or greater,
a thickness of the second gettering layer from the surface of the tube is 10 nm or greater,
the first gettering layer and the second gettering layer comprise silicon (Si), and
the first gettering layer and the second gettering layer further comprise at least one of phosphorus (P), oxygen (O), carbon (C), and nitrogen (N).

14. The substrate processing apparatus of claim 11, further comprising a vertical driving device configured to drive the boat in a vertical direction,
wherein:
in the annealing mode, the controller controls the vertical driving device such that the boat loaded with the at least one substrate is introduced into the reaction space, and,
when the transition metal is extracted into the first gettering layer and the second gettering layer, controls the vertical driving device to move the boat out of the reaction space.

15. The substrate processing apparatus of claim 11,
wherein, in the annealing mode:
the at least one substrate is disposed on the first gettering layer, and
a portion of a bottom surface of the at least one substrate is in contact with the first gettering layer.

16. The substrate processing apparatus of claim 15, wherein, in the annealing mode:
at least one of a sidewall surface and a upper surface of the at least one substrate is in contact with the first gettering layer,
the controller controls the gettering source gas supply device to supply an annealing gas from about 10 atm to about 100 atm to the reaction space, and
the annealing gas comprises at least one of hydrogen gas (H₂), deuterium gas (D₂), and nitrogen gas (N₂).

17. The substrate processing apparatus of claim 11, further comprising a vibration device configured to vibrate the boat,
wherein the controller controls the vibration device to apply vibration to the boat to unload the at least one substrate from the boat.

18. The substrate processing apparatus of claim 11, further comprising a cleaning gas supply device configured to supply a cleaning gas to the reaction space,
wherein:
the controller controls, in a cleaning mode, the cleaning gas supply device to supply the cleaning gas into the reaction space when the boat in which the at least one substrate is not loaded is introduced into the reaction space,
the cleaning mode is an operation mode for etching the first gettering layer comprising the transition metal and the second gettering layer comprising the transition metal, and
the cleaning gas comprises at least one of chlorine gas (Cl₂), hydrogen bromide gas (HBr), fluorine gas (F₂), and chlorine trifluoride gas (ClF₃).

19. A substrate processing apparatus comprising:
a boat configured to accommodate at least one substrate;
a tube configured to define a reaction space of the at least one substrate;
a heating device surrounding the boat and configured to heat the reaction space;
a gettering source gas supply device configured to supply a gettering source gas to the reaction space;
a cleaning gas supply device configured to supply a cleaning gas to the reaction space; and
a controller,
wherein the controller:
controls, in a gettering layer coating mode, the gettering source gas supply device to supply the gettering source gas into the reaction space when the boat is introduced into the reaction space,
controls, in an annealing mode, the heating device to heat the reaction space to a temperature of 500 °C or higher when the boat loaded with the at least one substrate is introduced into the reaction space, and
controls, in a cleaning mode, the cleaning gas supply device to supply the cleaning gas into the reaction space when the boat is introduced into the reaction space, and
wherein:
the gettering layer coating mode is an operation mode for forming a first gettering layer covering a surface of the boat and a second gettering layer covering a surface of the tube,
the annealing mode is an operation mode for extracting a transition metal from at least one substrate to the first gettering layer and the second gettering layer, and
the cleaning mode is an operation mode for etching the first gettering layer comprising the transition metal and the second gettering layer comprising the transition metal.

20. The substrate processing apparatus of claim 19, wherein:
the first gettering layer and the second gettering layer comprise at least one of phosphorus-doped silicon, phosphorus-doped silicon oxide, silicon carbide (SiC), silicon nitride (SiN), silicon oxide (SiO), and silicon carbonitride (SiCN), and,
in the annealing mode,
the at least one substrate is in contact with the first gettering layer.
